(19) United States
(12) Patent Application Publication
(10) Pub. No.: US 2010/0000620 A1
(43) Pub. Date: Jan. 7, 2010

(54) MICROFLUIDIC LIQUID-MOVEMENT DEVICE

(75) Inventors: Yves Fouillet, Voreppe (FR); Olivier Fuchs, Grenoble (FR); Raymond Campagnolo, Grenoble (FR); Jean-Maxime Roux, Grenoble (FR)

Correspondence Address: PEARNE & GORDON LLP, 1801 EAST 9TH STREET, SUITE 1200, CLEVELAND, OH, 44114-3108, US

(73) Assignee: COMMISSARIAT L'ENERGIE ATOMIQUE, Paris (FR)

(21) Appl. No.: 12/497,872

(22) Filed: Jul. 6, 2009

(30) Foreign Application Priority Data
Jul. 7, 2008 (FR) 08 54596

(51) Int. Cl. F15C 1/04; B81B 7/02

(52) U.S. Cl. 137/827; 137/833

(57) ABSTRACT

The invention concerns a microfluidic liquid-movement device.

The movement device according to the invention comprises a microchannel (10) provided with an opening (11B) onto the environment, the microchannel (10) being filled with a first liquid (F₁) and a second liquid (F₃), the two liquids being separated by a separating fluid (F₂). Injection of the second liquid (F₃) through the opening (11B) is obtained by movement of the first liquid (F₁) by electrowetting.

### TECHNICAL FIELD

The present invention relates to the general field of microfluidics and concerns a device for moving liquid in a microchannel.

The invention applies in particular to the injection of liquid out of the device provided for this purpose, with a view to carrying out biochemical, chemical or biological analyses, or for therapeutic purposes.

### PRIOR ART

Microfluidics is a research field that has been expanding rapidly for about ten years, because in particular of the design and development of chemical or biological analysis systems, referred to as lab-on-chip.

This is because microfluidics makes it possible to effectively manipulate small volumes of liquid. It is then possible to perform, on one and the same medium, all the steps of analysing a liquid sample, in a relatively short time and using small volumes of sample and reagents.

Depending on the application, the manipulation of small volumes of liquid sometimes makes it necessary to effect an injection of a defined volume of liquid in a given zone,

For example, in the medical field an application may require injecting a defined volume of liquid into the body of a patient for the purpose of treatment or with a view to establishing a diagnosis. The liquid may then be a medication, a radioactive tracer, or any other suitable substance.

For this purpose, a liquid-movement device enabling the liquid to be injected into a medium external to the device is necessary. It is essential that the movement device presents no risk, in terms of safety, for the body or the zone intended to receive the liquid to be injected. In addition, it is essential to control both the quantity of liquid injected and the injection rate.

The document US-A1-2003/006140 describes a device for atomising liquid in the form of droplets by variable dielectric pumping, the operating principle of which is based on the phenomenon of dielectrophoresis.

The functioning is as follows, with reference to FIG. 1, which shows schematically the device according to the prior art in a longitudinal section.

A microchannel A10 comprises an internal wall, the bottom and top faces of which each comprise a flat electrode A31, A32 extending along the longitudinal axis of the microchannel and disposed facing each other.

A slug of isolating liquid AF₁ is situated between these electrodes, surrounded upstream and downstream along the longitudinal axis by an isolating surrounding fluid AF₂. Liquid slug refers to a long drop contained in a channel or tube. The terms upstream and downstream are defined with reference to the direction X parallel to the axis of the microchannel A10.

The liquid slug AF₁ has a permittivity with a level higher than that of the surrounding fluid AF₂.

An electrical field is generated between the two electrodes A31 and A32, which has a gradient along the longitudinal axis of the microchannel. For this purpose, a potential difference is applied to the ends of the electrode A31 whereas the potential of the electrode A32 is fixed.

The movement of the liquid slug AF₁ along the longitudinal axis of the microchannel A10 is then obtained by dielectrophoresis. More precisely, the movement results from the appearance of a so-called dielectrophoretic force resulting from the difference in permittivity between the liquid slug AF₁ and the surrounding fluid AF₂, and the electrical field gradient that results from the tensions applied. The dielectrophoretic force tends to attract the high-permittivity liquid, here the liquid AF₁, towards the high-intensity zones of the electrical field.

The variation in tensions applied makes it possible to control the movement of the liquid slug AF₁, and consequently of the surrounding fluid AF₂, along the longitudinal axis of the channel A10.

The microchannel A10 also has at one end A12B an opening A11B allowing the ejection by atomisation of a liquid AF₃. The liquid to be atomised AF₃ is placed between the fluid AF₂ and the opening A11B.

Thus the movement of the liquid slug AF₁ in the direction of the end A12B of the microchannel A10 causes a movement of the liquid AF₃ in the same direction and the atomisation thereof in the form of droplets through the opening A11B.

The liquid-ejection device according to the prior art does however have a certain number of drawbacks.

Dielectric pumping by dielectrophoresis requires the use of high electrical voltages, which may be limiting depending on the application of the ejection device. Thus, for a medical application in which the device is used close to a surface to be treated sensitive to electrical fields, such as the body of a patient, the device according to the prior art obviously presents a safety problem.

In addition, the dielectrophoretic force depends on the height d of the dielectric in (d⁻¹), that is to say here the height of the isolating liquid slug AF₁ between the electrodes A31 and A32. In the case of the use of a very high microchannel, such as for example a few hundreds of micrometres, it is necessary to substantially increase the intensity of the electrical field applied in order to obtain a force of sufficient intensity, which firstly increases the risks for the surface to be treated and secondly makes the control electronics complex and requires bulky batteries.

In addition, the electrical consumption is high for producing a high-intensity electrical field.

Moreover, the operating principle of the dielectric pump makes the device according to the prior art limited to the use of two dielectric liquids AF₁ and AF₂ and excludes any electrically conductive liquid.

Finally, the arrangement of the electrodes A31 and A32 forms the air gap of a flat capacitor. The device is then limited to one microchannel with a rectangular transverse section. A square transverse section would make edge effects of the electrical field appear, which would be detrimental to the electrophoretic force and therefore the functioning of the device according to the prior art. In addition, the arrangement of the electrodes A31 and A32 in a microtube, that is to say a microchannel with a circular transverse section, cannot be achieved simply.

One solution for avoiding these drawbacks could be the use of a mechanical piston disposed inside the microchannel and exerting a pressure force on the liquid to be atomised. However, there exist not insignificant risks of leakage between the piston and the walls of the microchannel that might make the liquid-movement device inoperative.

### DISCLOSURE OF THE INVENTION

The aim of the present invention is to at least partly remedy the aforementioned drawbacks and to propose in particular a liquid-movement device the movement of which is obtained by the generation of a low-intensity electrical field.

To do this, the subject matter of the invention is a liquid-movement device, comprising at least one substrate comprising a microchannel, said microchannel comprising a first end and a second end, substantially opposite to each other in the longitudinal direction of the microchannel, an opening onto the surrounding environment being situated substantially at said second end.

Said device comprises:
a first liquid partially filling the microchannel in the longitudinal direction of the microchannel,

a fluid situated downstream of said first liquid in the direction of the second end and forming with the first liquid a first interface, said first interface being situated in a control portion of the microchannel, and
a second liquid situated downstream of said fluid in the direction of the second end and forming with the fluid a second interface.

According to the invention, the device comprises means of moving the first liquid by electrowetting, the first liquid being electrically conductive and the fluid electrically insulating, the movement of the first liquid causing the movement of the second liquid, via the fluid, through said opening.

Said means of moving the first liquid by electrowetting may comprise:
at least one first electrically conductive means,
a layer of a dielectric material directly covering the first conductive means, said dielectric layer being at least partially wetted by said first liquid,
at least one second electrically conductive means forming a counter-electrode, in contact with the first liquid, and
a first voltage generator for applying a potential difference between said first and second conductive means.

According to one embodiment of the invention, the substrate comprising the control portion being electrically conductive, the first electrically conductive means comprises the conductive substrate.

Preferably, the microchannel comprises an injection portion extending substantially from the opening in the direction of the control portion, said second interface being situated in the injection portion. In this case, a stack of a first layer of a dielectric material, an electrically conductive means being able to be taken to a given potential and a second layer of a dielectric material is disposed on the internal wall of the injection portion so as to electrically insulate the second liquid from the conductive substrate. Each element of said stack has a length substantially equal in the longitudinal direction of the injection portion.

According to one embodiment of the invention, said first electrically conductive means comprises at least one electrode disposed on at least part of the wall in the longitudinal direction of the microchannel and situated in the control portion.

Advantageously, said first electrically conductive means comprises an electrode extending over the entire length of the control portion.

Preferably, the liquid-movement device comprises a reservoir communicating with the microchannel through an opening situated at the first end and containing said first conductive liquid.

Said first electrically conductive means can comprise a matrix of electrodes extending over the entire length of the control portion.

Advantageously, the first liquid forms a liquid slug surrounded by fluid so as to form a rear interface and a front interface, the two interfaces being situated in the control portion.

Advantageously, the movement of the first interface in the direction of the first end of the microchannel causes an aspiration of the second liquid through the opening in the direction of the first end.

Said electrode can comprise two parts parallel to each other.

Preferably, said electrode extends over the entire perimeter of the control portion. Thus said electrode comprises only a part, the circumferential surface of which is substantially continuous.

Advantageously, said layer of dielectric material is directly covered with a layer of hydrophobic material.

The microchannel can have a convex polygonal transverse section.

Alternatively, the microchannel can have a substantially circular transverse section.

According to one embodiment of the invention, the microchannel has a plurality of control portions disposed in series, each control portion being partially filled with the first liquid and fluid.

According to another embodiment of the invention, the microchannel has a plurality of control portions disposed in parallel, each control portion being partially filled with the first liquid and with fluid.

The longitudinal axis of the control portions can be substantially perpendicular to the longitudinal axis of the injection portion.

According to one embodiment of the invention, the height of the injection portion is substantially greater than the height of the control portion.

Advantageously, the height of the injection portion is between substantially 10 and 50 times the height of the control portion.

A connection portion can connect the control portion to the injection portion, the connection portion being filled only with fluid.

According to one embodiment of the invention, the microchannel comprises an injection portion extending substantially from the opening in the direction of the control portion, said second interface being situated in the injection portion. A system for filling with second liquid is then connected to the microchannel at the injection portion and comprises a reservoir filled with second liquid communicating with the injection portion by means of a valve.

The latter may be a three-way valve.

Said valve can be disposed so as to divide the injection portion into a storage part communicating with the control portion and in which the second interface is situated, and an injection part communicating with the opening of the second end, and can be adapted to occupy alternately two states:
a first so-called filling state, in which the reservoir communicates with the storage part,
a second so-called injection state, in which the flow of second liquid coming from the reservoir is blocked, the storage part communicating with the injection part.

According to a variant, two microchannels are disposed in parallel and connected to each other so as to have in common the second end provided with the opening, each microchannel comprising an injection portion extending substantially from the opening in the direction of the respective control portion, said second interface being situated in the injection portion. A system for filling with second liquid is connected to the microchannels so as to divide each injection portion into:
a storage part particular to each microchannel, communicating with each control portion, in which the second interface is situated, and
an injection part common to the two microchannels communicating with the opening of the second end,

said filling opening comprising a reservoir filled with second liquid communicating with the microchannels by means of a valve.

Said valve may be a four-way valve.

It can be adapted to occupy alternately two states:
a first state in which the reservoir communicates with the storage part of a first channel while the storage part of the second microchannel communicates with the injection part,
a second state in which the reservoir communicates with the storage part of the second microchannel while the storage part of the first microchannel communicates with the injection part.

The flow rate of second liquid through the opening may be constant.

Advantageously, the liquid-movement device comprises a system controlling the movement of the first liquid according to the position of the first interface or of the second interface of the fluid situated in the microchannel, said system controlling the movement of the first liquid comprising a capacitive measuring device for controlling the movement of the first liquid according to the capacitance measured.

According to one embodiment, the capacitive measuring device is adapted to determine the position of the first interface, and comprises:
said control electrode forming a detection electrode,
said control counter-electrode forming a detection counter-electrode,
a second voltage generator for applying a potential difference between said detection electrode and said detection counter-electrode,
means of measuring the capacitance formed between said detection electrode and said detection counter-electrode.

According to a variant, the capacitive measuring device is adapted to determine the position of the second interface, and comprises:
at least one detection electrode disposed on at least part of the wall of the microchannel defining a detection portion situated downstream of said control portion, said second interface being situated in said detection portion,
an electrically conductive means forming a detection counter-electrode, in contact with the second liquid,
a second voltage generator for applying a potential difference between said detection electrode and said detection counter-electrode,
means of measuring the capacitance formed between said detection electrode and said detection counter-electrode.

The capacitive measuring device can comprise calculation means, connected to the measuring means, in order to determine the position of the interface according to the capacitance measured.

The capacitive measuring device can comprise control means, connected to the calculation means and to the first voltage generator, in order to control the potential difference applied by the latter.

According to one embodiment, the second liquid being electrically conductive, a layer of dielectric material covers the detection means.

According to a variant, the second liquid is dielectric, the permittivity of which is different from that of the fluid.

Preferably the measuring means comprise a capacitor connected in series with the detection means, and a voltmeter for measuring the voltage at the terminals of said capacitor.

Alternatively, the measuring means comprise an impedance analyser.

Said detection means can comprise a plurality of elementary detection electrodes.

In this case, said substrate can be taken to a potential determined by an electrically conductive means. The latter advantageously comprises an electrode disposed on an external face of the substrate and extending over the entire length of the detection means.

Other advantages and features of the invention will emerge in the following non-limitative detailed description.

### BRIEF DESCRIPTION OF THE DRAWINGS

A description will now be given, by way of non-limitative examples, of embodiments of the invention, with reference to the accompanying drawings, in which:

FIG. 1, already described, is a schematic representation in longitudinal section of a liquid atomisation device according to the prior art;

FIGS. 2A to 2C show the operating principle of the movement of drops by electrowetting;

FIG. 3 shows the operating principle of the movement of liquid by electrowetting, in a closed configuration of a liquid-movement device;

FIGS. 4A and 4B are schematic depictions in longitudinal section of a liquid-movement device according to the first preferred embodiment of the invention, for two steps of the operation;

FIG. 5 is a schematic representation in longitudinal section of a liquid-movement device according to a variant of the first preferred embodiment of the invention in which a matrix of control electrodes is provided;

FIG. 6 is a schematic representation in longitudinal section of a liquid-movement device according to the second preferred embodiment of the invention;

FIG. 7 is a schematic representation in longitudinal section of a liquid movement device according to a third embodiment of the invention, in which a plurality of control portions disposed in series is provided;

FIG. 8 is a schematic representation in longitudinal section of a liquid movement device according to a fourth embodiment of the invention, in which a plurality of control portions disposed in parallel is provided;

FIG. 9 is a schematic representation in longitudinal section of a part of the microchannel of the liquid-movement device according to a fifth embodiment of the invention, making it possible to reduce the effects of hysteresis of the contact angle;

FIGS. 10A and 10B are schematic representations in longitudinal section of a liquid-movement device according to a sixth embodiment of the invention, for two steps of the operation;

FIGS. 11A and 11B are schematic representations in longitudinal section of a liquid-movement device according to a variant of the sixth embodiment of the invention for two steps of the operation;

FIGS. 12A, 12B, 13A and 13B are schematic representations in longitudinal section of a liquid-movement device according to a seventh embodiment of the invention, provided with a system of controlling the movement of the piston liquid. FIGS. 13A and 13B show variants of the seventh embodiment shown in FIGS. 12A and 12B.

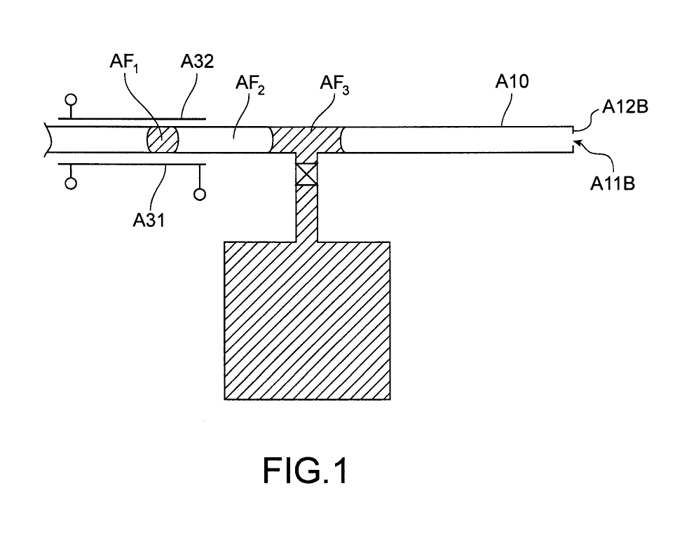

### DETAILED DISCLOSURE OF A PREFERRED EMBODIMENT

A device according to the invention uses a device for moving liquid, by electrowetting, or more precisely by electrowetting on dielectric.

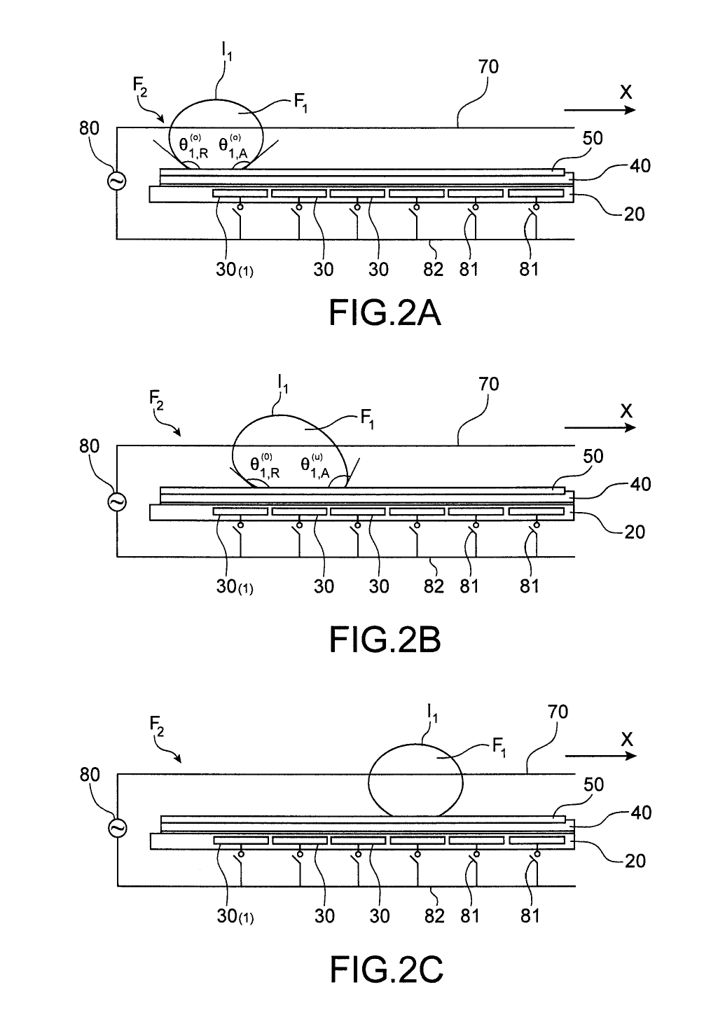

The principle of electrowetting on dielectric used in the context of the invention can be illustrated by means of FIGS. 2A-2C, in the context of a device of the open type.

A drop of an electrically conductive liquid F₁ rests on an array of electrodes 30, from which it is insulated by a dielectric layer 40 and a hydrophobic layer 50 (FIG. 2A). There is therefore a hydrophobic insulating stack.

The hydrophobic character of this layer means that the drop has a contact angle, on this layer, greater than 90°.

It is surrounded by a dielectric fluid F2, and forms with this fluid an interface I₁.

The electrodes 30 are themselves formed on the surface of a substrate 20.

A counter-electrode 70, here in the form of a catenary wire, makes it possible to maintain electrical contact with the drop F₁. This counter-electrode can also be a buried wire or a planar electrode in the cap of a confined system.

The electrodes 30 and the counter-electrode 70 are connected to a voltage source 80 for applying a voltage U between the electrodes.

When the electrode 30(1) situated close to the drop F₁ is activated, by switching means 81 the closure of which establishes a contact between this electrode and the voltage source 80 via a common conductor 82, the assembly consisting of drop under tension F₁, dielectric layer 40 and activated electrode 30(1) acts as a capacitor.

As described by the article by Berge entitled “Electrocapillarité et mouillage de films isolants par l“eau”, C.R. Acad. Sci., 317, series 2, 1993, 157-163, the contact angle of the interface of the drop F₁ facing the activated electrode 30(1) then decreases in accordance with the equation:

$$cos {θ}_{1}^{( U )} = cos {θ}_{1}^{( 0 )} + \frac{1}{2} \frac{{ɛ}_{r}}{e σ} {U}^{2}$$

where e is the thickness of the dielectric layer 40, ∈ᵣ the permittivity of this layer and σ the surface voltage of the interface of the drop.

When the biasing voltage is alternating, the liquid behaves as a conductor when the frequency of the biasing voltage is substantially less than a cutoff frequency, the latter, depending in particular on the electrical conductivity of the liquid, is typically around a few tens of kilohertz (see for example the article by Mugele and Baret entitled “Electrowetting: from basics to applications”, J. Phys. Condens. Matter, 17 (2005), R705-R744). In addition, the frequency is substantially greater than the frequency making it possible to exceed the hydrodynamic response time of the liquid F₁, which depends on the physical parameters of the drop such as the surface tension, the viscosity or the size of the drop, and which is around a few hundreds of hertz.

The response of the drop F₁ then depends on the mean square value of the voltage, since the contact angle depends on the voltage in U².

According to the article by Bavière et al entitled “Dynamics of droplet transport induced by electrowetting actuation”, Microfluid, Nanofluid, 4, 2008, 287-294, an electrostatic pressure acting on the interface I₁ appears, close to the contact line. If this electrostatic pressure is applied asymmetrically, the drop F₁ can then be moved. In FIG. 2A, the activation of the electrode 30(1) sets the drop in motion in the direction X.

The drop can thus possibly be moved gradually (FIGS. 2B and 2C), over the hydrophobic surface 50, by successive activation of the electrodes 30(1), 30(2), etc, along the catenary 70.

It is therefore possible to move liquids, but also to mix them (by bringing together drops of different liquids), and to implement complex protocols.

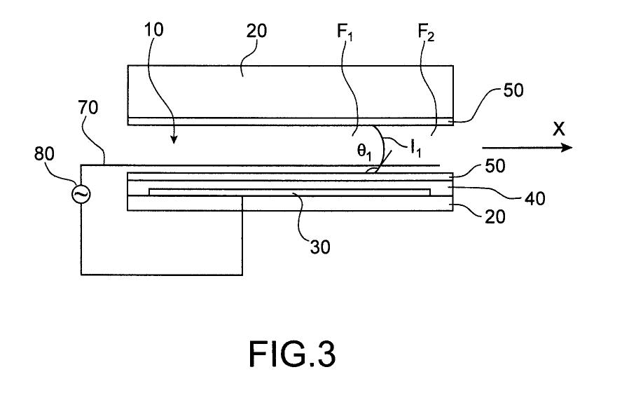

FIG. 3 illustrates the phenomenon of movement of a liquid by electrowetting in a device of the closed or confined type comprising a microchannel.

In this figure, the numerical references identical to those in FIGS. 2A-2C designate the same elements.

The microchannel 10 is partially filled with the conductive liquid F₁ forming an interface I₁ with the dielectric fluid F₂.

In this example, the matrix of electrodes 30 is replaced by a single electrode 30.

When the electrode 30 is not activated, the interface I₁ is static, and the liquid F₁ and fluid F₂ are at rest.

When the electrode 30 is activated, the original electrostatic pressure appears and acts on the interface I₁, which sets the liquid F₁ in motion in the direction X.

The liquid F₁ can thus be moved over the hydrophobic surface 50 by activation of the electrode 30. The fluid F₂ is then “pushed” by the liquid F₁.

Examples of devices using this principle are described in the article by Pollack et al entitled “Electrowetting-based actuation of droplets for integrated microfluidics”, Lab Chip, 2002, 2, 96-101.

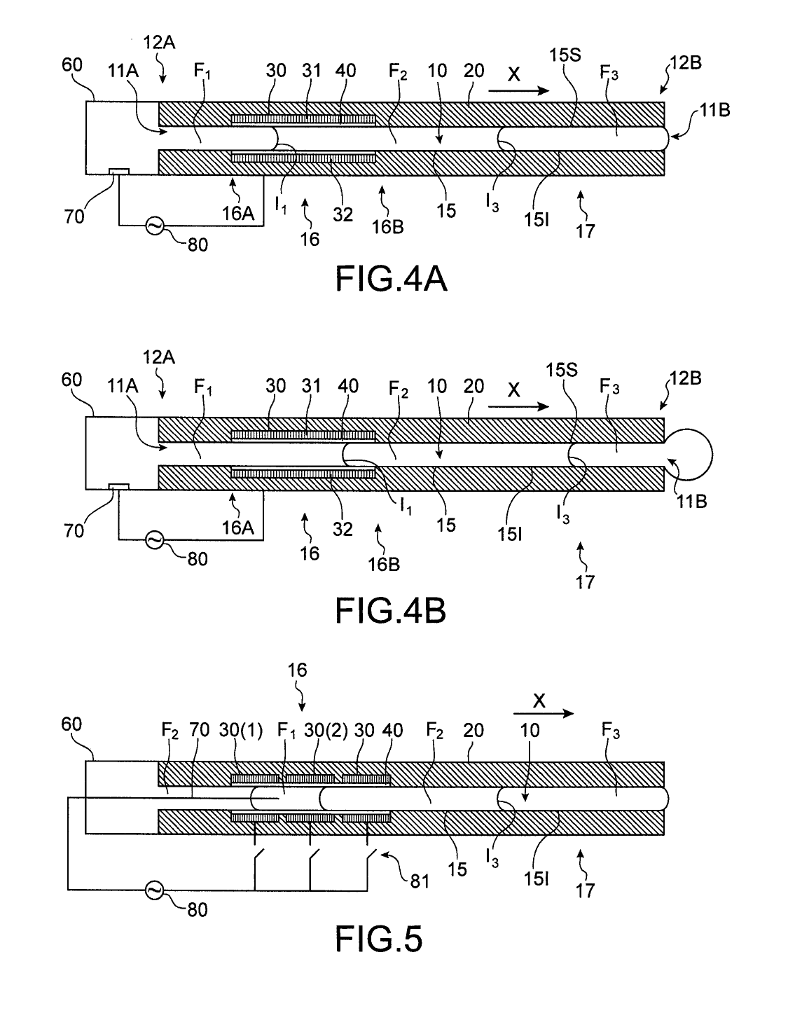

A first preferred embodiment of the invention is shown in FIGS. 4A and 4B, which show, in longitudinal section, a microfluidic liquid-movement device.

In this figure, the numerical references identical to those in FIG. 3 designate the same elements.

With reference to FIG. 4A, the microchannel 10 comprises a first end 12A comprising a first opening 11A and a second end 12B opposite to the first end 12A in the longitudinal direction of the microchannel 10 and comprising a second opening 11B.

The microchannel 10 can have a convex polygonal transverse section, for example square, rectangular or hexagonal. It is considered here that a square section is a particular case of the more general rectangular shape. It may also have a circular transverse section.

The term microchannel is taken in a general sense and comprises especially the particular case of the microtube, the cross section of which circular.

Throughout the following description, the terms height and length designate the size of the microchannel 10 or of a portion of the microchannel 10 in the transverse and longitudinal directions respectively. Thus, for a microchannel with a rectangular cross section, the height corresponds to the distance between the bottom and top walls of the microchannel, and for a microchannel with a circular cross section the height designates the diameter thereof.

In addition, it should be noted that the verbs “cover”, “be situated on” and “be disposed on” may not imply direct contact. Thus a material may be disposed on a wall without there being direct contact between the material and the wall. Likewise, a liquid may cover a wall without there being direct contact. In these two examples, an intermediate material may be present. Direct contact is assured when the qualifier “directly” is used with the previously mentioned verbs.

A control electrode 30 is disposed directly on at least one face of the internal wall 15 of the substrate 20 and extends in the longitudinal direction of the microchannel 10. It is said to be buried. The electrode 30 extends over part or all of the perimeter of the microchannel 10.

The insulating layer 40 and the hydrophobic layer (not shown) that cover the electrode 30 may be a single layer combining these two functions, for example a layer of Parylene.

In the example shown, the counter-electrode 70 is introduced into the liquid F₁ at the reservoir 60, in the form of one or more points of electrical contact with the conduct liquid F₁. It may also be a catenary in the form of an electrically conductive wire, for example made form Au (shown in FIG. 5).

The voltage source 80, preferably AC voltage, is connected to the electrode 30 and to the counter-electrode 70. The frequency is preferably between 100 Hz and 10 kHz, preferably around 1 kHz.

Thus the response of the liquid F₁ depends on the mean square value of the voltage applied since the contact angle depends on the voltage in U², in accordance with the equation given previously. The mean square value can vary between 0V and few hundreds of volts, for example 200V. It is preferably around a few tens of volts.

The length of the electrode 30 in the longitudinal direction of the microchannel 10 defines a control portion 16.

The control portion 16 comprises a first end 16A in the direction of the first end 12A of the microchannel 10 and a second end 16B in the direction of the second end 12B in the longitudinal direction of the microchannel 10.

Injection portion 17 means the portion of the microchannel 10 extending from the second end 12B of the microchannel 10 in the direction of the control portion 16.

A reservoir 60 able to contain the liquid F₁ can be connected to the microchannel 10 by means of the opening 11A of the end 12A and is intended to supply the microchannel 10 with piston liquid F₁.

The interface I₁ is situated in the control portion 16. The triple line of the interface I₁ is contained in a plane substantially transverse to the microchannel 10.

The microchannel 10 also comprises a second liquid F₃, referred to as the liquid of interest, which partially fills the channel as from substantially the second end 12B. The second liquid F₃ is in contact with the fluid F₂. The interface between these two fluids forms an interface I₃.

The interface I₃ is in contact with the internal wall 15 of the microchannel 10. The connection line between the interface I₃ and the wall 15 defines a triple line and a contact angle θ₃ can be measured in the liquid F₃. The triple line of the interface I₃ is contained in a substantially transverse plane of the microchannel 10.

The interface I₃ is situated in the injection portion 17 and therefore outside the control portion 16.

The piston liquid F₁ is electrically conductive and may be an aqueous solution charged with ions, for example Cl⁻, K⁺, Na⁺, Ca²⁺, Mg²⁺, Zn²⁺, Mn²⁺ or others. The piston liquid F₁ may also be mercury, gallium, eutectic gallium or ionic liquids of the bmin PF6, bmin BF4 or tmba NTf2 type.

The liquid of interest F₃ may be a liquid adapted to a chemical, biological or medical application. In the latter case, the liquid F₃ may in particular be a medicinal liquid or a liquid containing active agents, molecules or a radioactive tracer.

The fluid F₂ is electrically insulating. It may be a gas, for example air, or a liquid such as an alkane, for example hexadecane or undecane, or a silicone or mineral oil, or fluorinated solvents, for example FC-40® of FC-70®. In the case of silicone oil, the dynamic viscosity is preferably substantially less than approximately 10 cp. Preferably the fluid F₂ is biologically compatible with the liquid F₃.

The fluid F₂ is non-miscible with the piston liquid F₁ and with the liquid of interest F₃.

The microchannel has a length of between 100 μm and 500 mm, preferably between 500 μm and 100 mm.

The height or diameter of the microchannel 10 is typically between a few nanometres and 200 μm, and preferably between 1 μm and 100 μm.

The reservoir can have a capacity of between a few nanometres and 1 ml.

The substrate 20 may be made from silicon or glass, polycarbonate, polymer or ceramic. In the case of a silicon substrate, it is preferable to provide an insulating layer on the surface, this insulating layer can be deposited or result from a thermal oxidation. The electrode 30 is obtained by deposition of a fine layer of a metal chosen from Au, Al, ITO, Pt, Cu, Cr etc or an Al—Si etc alloy by virtue of conventional microtechnologies in microelectronics, for example by photolithography.

The thickness of the electrode is between 10 nm and 1 μm, preferably 300 nm. The length of the electrode 30 is from a few micrometres to a few millimetres.

The electrode 30 is covered with a dielectric layer of Si₃N₄, SiO₂, etc with a thickness of between 100 nm and 3 μm, preferably between 300 nm and 1 μm. The dielectric layer of SiO₂ can be obtained by thermal oxidation.

Finally, a hydrophobic layer can be deposited on the substrate. For this purpose, a deposition of Teflon by dipping or spraying or of SiOC deposited by plasma can be effected. A deposition of hydrophobic silane in vapour or liquid phase can be carried out. Its thickness will be between 100 nm and 3 μm, and preferably between 300 nm and 1 μm.

The operating principle is as follows, with reference to FIGS. 4A and 4B.

As shown by FIG. 4A, the interface I₁ is situated in the control portion 16. Initially, it is preferably situated close to the first end 16A of this portion.

The activation of the electrode 30 by the voltage source 80 causes the movement of the liquid F₁ in the direction of the second end 16B of the control portion 16.

Consequently the liquid F₁ “pushes” the fluid F₂ in the same direction, that is to say in the direction of the second end 12B of the microchannel 10, and at the same time “pushes” the liquid of interest F₃.

As from the moment when the liquid F₃ reaches the second opening 11B, a quantity of liquid F₃ is injected outside the movement device corresponding to the quantity of liquid F₃ moved.

When the interface I₁ reaches the second end 16B of the control portion 16, the liquid F₁ substantially covers the electrode 30 in its entirety. The triple line is then no longer subjected to the electrowetting force. The contact angle θ₁ increases up to its value corresponding to the absence of an electrical field imposed and the liquid F₁ is immobilised.

Consequently the liquid F₁ no longer causes the movement of the fluid F₂, which is immobilised, as well as the liquid of interest F₃, which is then no longer injected.

The device according to the invention has a certain number of advantages.

The separating fluid F₂ also makes it possible to avoid mixing between the piston liquid F₁ and the liquid of interest F₃, which could denature the physical, chemical or biological properties of the liquid of interest F₃.

The dielectric separating fluid F₂ allows the use of any type of liquid of interest F₃, whatever the chemical composition and the electrical conductivity of the latter.

Moreover, the control electrode 30 can occupy only part of the perimeter of the control portion 16.

Thus, in the case of a microchannel 10 with a rectangular cross section for example, the electrode 30 can comprise a top part 31 (FIG. 4A) disposed directly on a top wall 15S of the microchannel 10, and a bottom part 32 disposed directly on a bottom wall 15I of the microchannel 10, the two parts 31 and 32 being parallel to each other. This arrangement is particularly adapted for a rectangular cross section since the lateral walls have a surface area substantially less than that of the top and bottom walls 15S and 15I. The edge effects of the electrical field are thus minimised.

Nevertheless, the electrode 30 can also be disposed on the whole of the perimeter of the control portion 16. The electrode 30 is then disposed on all the top 15S, bottom 15I and lateral walls or, in the case of a circular cross section, over the entire periphery of the control portion 16.

This arrangement has the advantage of applying the electrowetting force on the whole of the triple line of the interface I₁. The curvature of the interface I₁ is then uniformly modified, which makes the capillary pressure at the interface between the two fluids F₁ and F₂ uniform.

This is because the triple line of the interface I₁ remains substantially contained in a transverse plane of the control portion 16.

The movement of the interface I₁ is then more effective, which makes it possible to obtain a more precise control of the injection rate and of the injected volume of the liquid F₃.

If the electrowetting force were not uniform along the triple line, the plane containing the triple line of the interface I₁, would no longer be substantially transverse to the control portion 16. The liquid F₁ could move for example in the direction of the second end 12B of the channel 10 and the fluid F₂ move in the opposite direction, which is to be avoided.

According to a variant of the first embodiment of the invention shown in FIG. 5, a matrix of independent electrodes 30 is disposed directly on at least one face of the substrate 20, as described previously with reference to FIGS. 2A to 2C.

As before, a control portion 16 of the microchannel 10 is defined as being the portion extending in the longitudinal direction of the microchannel 10 and which comprises the matrix of electrodes 30.

The spacing between adjoining electrodes 30 can be between substantially a few micrometres and few tens of micrometres.

In this variant and in accordance with the embodiment in FIGS. 2A to 2C, it is advantageous for the liquid F₁ to be in a form of a liquid slug entirely placed in the control portion 16. The liquid can thus be moved gradually, over the hydrophobic layer 50 of the control portion 16, by successive activation of the electrodes 30(1), 30(2) . . . of the matrix of electrodes.

One advantage of this embodiment is to be able to control the movement of the drop of liquid F₁ in the two directions X and −X, according to the activation of the electrodes 30.

It is thus possible to achieve not only the injection of the liquid F₃ out of the device, but also the suction of the liquid F₃, that is to say the movement of the liquid F₃ in the direction of the control portion 16.

The suction of the liquid F₃ can make it possible to fill the microchannel 10 with liquid F₃, for example from a reservoir of liquid F₃, with a view to subsequent use of the device according to the invention.

It is also possible to aspirate a liquid other than the liquid F₃ after injection thereof. For example, it is possible to take in vivo a sample of liquid, after injection of the liquid F₃, for the purpose of analysing it subsequently.

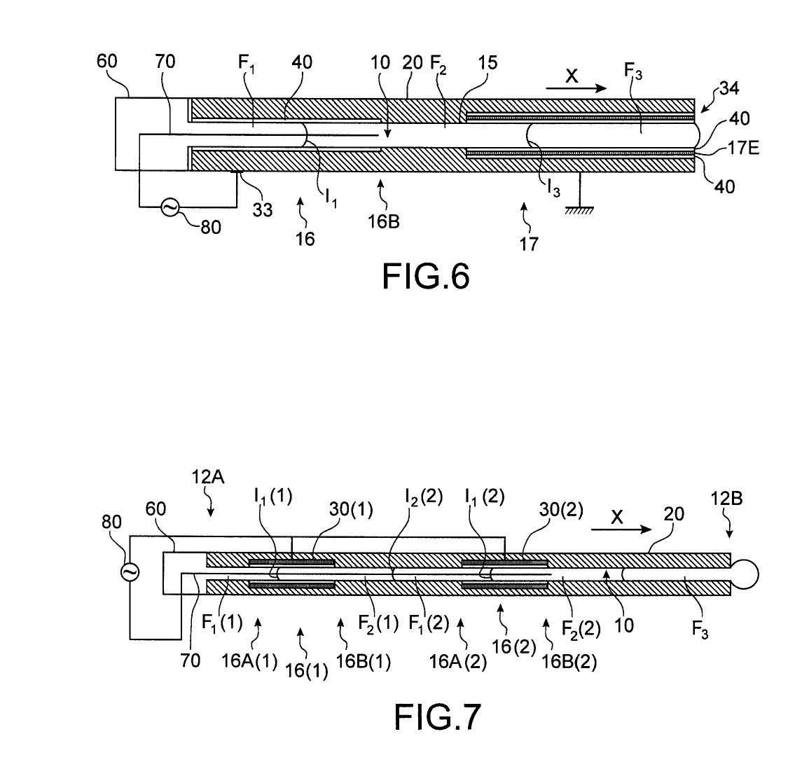

A second preferred embodiment will now be described in detail with reference to FIG. 6, which shows a schematic representation in longitudinal section of the movement device, in which the control electrode 30 is replaced by the substrate 20, advantageously biased.

For this purpose, the substrate 20 is electrically conductive. It can be produced from silicon doped in order to increase its electrical conductivity. The doping can correspond to 5.10¹⁸ atoms/cm² in n or p.

An electrode 33, connected to the voltage source 80, is disposed so as to apply the given potential difference to the substrate 20 and to the counter-electrode 70.

A dielectric layer 40 is directly disposed on part of the internal wall 15 of the microchannel 10 so as to electrically insulate the piston liquid F₁ from the biased substrate 20. The dielectric layer 40 can be directly disposed on the internal wall 15 from the reservoir 60 as far as the second end 16B of the control portion 16, and over the entire perimeter.

A hydrophobic layer (not shown) may be directly disposed on the dielectric layer 40.

Thus the biased substrate 20, the dielectric layer 40 and the biased piston liquid F₁ form a capacitor. Since the piston liquid F₁ directly partially covers the dielectric layer 40 in the control portion 16, an electrowetting force applied to the triple line of the interface I₁ can be generated.

In addition, for the purpose of electrically insulating the liquid of interest F₃ from the biased substrate 20, a stack 34 of a first dielectric layer 40, an electrode 17E and then a second dielectric layer 40, each having substantially equal lengths in the longitudinal direction, is disposed directly on the internal wall 15 of the injection portion 17.

The electrode 17E can be grounded, so as not to cause electrowetting effects at the triple line of the interface I₃.

A third embodiment of the invention will now be described in detail with reference to FIG. 7, which shows a schematic representation in longitudinal section of the movement device, which comprises a plurality of control portions disposed in series.

The third embodiment is an improvement to the first preferred embodiment and comprises substantially the same components as in the first embodiment.

As shown by FIG. 7, two control portions 16(1). 16(2) are disposed in series. However, it is possible to dispose a number n of control portions 16 without being limited to two portions.

In the general case where n control portions are provided, each control portion 16(i), where i∈ [1,n], has a first end 16A(i) and a second end 16B(i). The control portions 16(i) are arranged in series along the microchannel 10 so that a second end 16B(i) is situated close to the first end 16A(i+1) of the control portion 16(i+1) situated downstream of the control portion 16(i).

Each control portion 16(i) is partially filled with conductive piston liquid F₁(i), each interface I₂(i) being initially situated between an end 16B(i−1) and 16A(i). A separating fluid F₂(i) fills the channel 10 between the interface I₁(i) and I₂(i+1).

The piston liquid F₁(i) is in contact with the separating fluid F₂(i) and forms an interface I₁(i) according to the same characteristics as in the first embodiment. It will be understood that the piston liquid F₁(i) fills both part of the control portion 16(i) and part of the channel situated between the control portions 16(i−1) and 16(i).

The control portion 16(1) is situated close to the first end 12A of the microchannel 10, which communicates with a reservoir 60.

The control portion 16(n) is situated close to the second end 12B of the microchannel 10. The separating fluid F₂(n) is in contact also with a liquid of interest F₃ that partially fills the microchannel 10 from the second end 12B of the microchannel and in the direction of the second end 16B(n) of the control portion 16(n).

The control portions 16(i) are spaced apart from each other by a distance from a few micrometers to a few millimetres.

Preferably this distance is defined so that the volume between the control portions 16(i) is substantially equal to the volume defined by each control portion 16(i) so that the piston liquid F₁(i) can fill substantially all the control portion F₁(i).

Each control portion 16(i) comprises a control electrode 30(i) or a matrix of control electrodes 30(i), as described in the first embodiment.

The device comprises a counter-electrode 70 intended to take the conductive liquids F₁(i) to a given potential. The counter-electrode 70 is a catenary wire, for example made from Au. It may be a buried wire or a plurality of planar electrodes disposed opposite the electrodes 30(i).

The control electrodes 30(i) and the counter-electrode 70 are connected to a voltage source 80.

The electrodes 30(i) are advantageously activated simultaneously.

The third embodiment of the invention has the advantage of increasing the injection pressure of the liquid F₃.

This is because the electrowetting forces applied to the interfaces I₁(i) are added together, which makes it possible to obtain a higher injection pressure for the liquid of interest F₃. In the case of control portions 16(i) identical in size and geometry, the injection pressure obtained is substantially equal to the number n of interfaces I₁(i) multiplied by the pressure obtained with a single control portion 16(i).

Several devices obtained according to embodiments 1 to 3 can be associated in a matrix structure, each device being able to be used independently, in parallel. According to another association, several devices obtained according to these same embodiments can be associated in a matrix structure limited to the control portions. In this case, the matrix of control portions can open out on a single injection portion, or on at least one injection portion, of reservoirs that may be common to several or to all the control portions. This type of association can be obtained by producing a network of channels 10 and reservoirs 60 in the plane and/or thickness of the substrate. These devices can be produced on different substrates and then stacked.

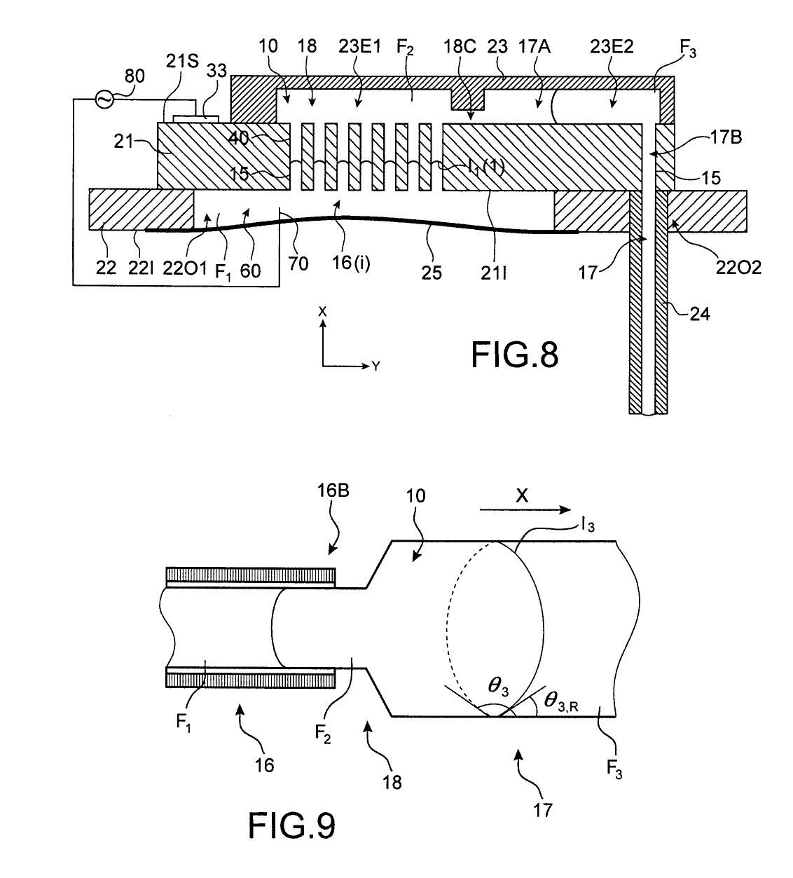

A fourth embodiment of the invention will now be described in detail with reference to FIG. 8.

FIG. 8 is a schematic representation in longitudinal section of a liquid-movement device having a plurality of control portions 16 in parallel.

A direct orthogonal reference frame (X,Y) is shown in FIG. 9, where the direction X is parallel to the longitudinal axis of the control portions 16.

Several substrates 21, 22, 23 are arranged so as to form a microchannel 10.

A first substrate 21 extends in the direction Y and has a thickness along X. The thickness of the substrate 10 is around a few hundreds of microns, for example 500 μm, 700 μm, or 1000 μm.

The first substrate 21 is made so as to obtain channels passing along the thickness of the substrate 21 thus defining control portions 16(i). The control portions 16(i) can be disposed in a honeycomb and have a diameter of around a few tens of microns. Preferably, each control portion 16(i) has a circular or hexagonal transverse section or having a form of the same type.

A through channel 17B with a large diameter is also produced and disposed close to one edge of the substrate 21. The channel 17B is intended to form an injection part 17B of the injection portion 17 of the microchannel 10.

A dielectric layer 40 is disposed on the wall of the substrate 21, or more precisely on the internal wall 15 of the control portions 16(i). The internal wall 15 of the channel 17B can also be covered with the dielectric layer 40.

A hydrophobic layer is disposed on the wall of the substrate 21.

The channels 16(i) and 17B can be obtained by plasma etching of the RIE type of the substrate 21. The substrate 21 is for example made from silicon. The diameter of the control portions 16(i) is between 1 μm and 100 μm, preferably substantially 30 μm. The diameter of the channel 17B can be around a few hundreds of microns.

The dielectric layer can be SiO₂ obtained by thermal oxidation.

The hydrophobic layer can be a layer of SiOC deposited by plasma. A deposit of hydrophobic silane in vapour or liquid phase can be used. Preferably, the bottom face 21I of the substrate 21 is protected from the deposition of the hydrophobic layer so as to keep a hydrophilic property.

A second substrate 22 is disposed so as to be in contact with the bottom wall 21I of the substrate 21. It comprises a first opening 22O1 that communicates with the control portions 16(i) and a second opening 22O2 that communicates with the channel 17B.

The second substrate 22 may be a fluidic card of the printed circuit type, for example in FR4, or ceramic, silicon, glass, or a polymer such as polycarbonate.

A flexible membrane 25 is disposed at the bottom face 22I of the substrate 22 so as to close the first opening 22O1 at its bottom end 22I. The membrane thus defines, with the substrates 21 and 22, a reservoir 60 able to contain the liquid F₁.

The flexible membrane may be thin film of elastomer or a bellows, bonded to the bottom face of the substrate 22.

A third substrate 23 is disposed on the top face 21S of the substrate 21. The substrate 23 comprises one or more recesses so as to form, in cooperation with the substrate 21, one or more cavities of the microchannel 10. More precisely, a first recess 23E1 of the substrate 23 is disposed substantially facing the control portions 16(i) so as to form a connection portion 18 of the microchannel 10. A second recess 23E2 is disposed substantially facing the channel 17B so as to form a storage part 17A.

The storage part 17A communicates with the injection part 17B so as to form together the injection portion 17 of the microchannel 10.

The recesses 23E1 and 23E2 have a height along Y of between 100 μm and a few millimetres, preferably 1 mm. The recess 23E1 can have a lower height that the recess 23E2 in order to limit the volume of fluid F₂ necessary.

The connecting portion 18 and the storage part 17A can communicate with each other by means of a communication conduit 18C with a height lying between a few tens of microns and few hundreds of microns, preferably 100 μm.

The third substrate 23 can be made of silicon or glass. It can be assembled to the first substrate 21 by adhesive screen printing. Direct anchoring can also be effected, by anodic welding or molecular bonding.

Finally, a tube 24 comprising a microchannel can be arranged so as to communicate with the channel 17B of the substrate 21. The purpose of the microchannel of the tube 24 is to extend the channel 17B in order to facilitate the injection of the liquid in a zone to be treated. The component 27 can also be a catheter, a needle comprising a microchannel, or a coupling between the channel 17B and a needle or catheter.

The liquids F₁, F₃ and the fluid F₂ fill the microchannel 10 in the following manner.

The piston liquid F₁ partially fills the control portions 16(i) in the direction X.

The fluid F₂ fills the connecting portion 18 and the communication conduit 18C. It also partially fills the control portions 16(i) so as to form an interface I₁(i) in each control portion 16(i) with the piston liquid F₁. It also partially fills the storage part 17A of the injection portion 17.

The liquid of interest F₃ partially fills the storage part 17A of the injection portion 17 so as to form an interface I₃ with the fluid F₂. The liquid of interest F₃ also fills the injection part 17B and at least partially the microchannel of the tube 24.

As described previously, the electrowetting force can be generated either from the activation of electrodes 30 disposed at the control portions 16(i), or from the activation of the biased substrate 21.

An electrode 70 forming a counter-electrode is disposed for example in the reservoir 60 in order to take the conductive piston liquid F₁ to a potential V0.

In the first case, each control portion 16(i) has the internal wall 15 covered with a metal layer forming an electrode 30. A dielectric layer 40 is disposed on the electrode 30.

The electrodes 30(i) and the counter-electrode 70 are connected to a voltage source 80.

The electrodes 30(i) can be connected to the voltage source 80 by means of a buried line (not shown) on the surface of the substrate 21 and an electrode 33 connected to the buried line and to the voltage source.

In the second case, the first substrate 21 is electrically conductive. It can be produced from silicon doped so as to increase the electrical conductivity. An electrode 33 is disposed in contact with the substrate 21 in order to take it to a given potential V1.

The dielectric layer 40 is disposed so as to electrically insulate the liquid F₁ from the biased substrate 21.

The substrate 21 and counter-electrode 70 are connected to a voltage source 80.

The operating principle of the movement device according to the fourth embodiment is identical to that of the first or second preferred embodiment and is therefore not repeated here.

The device then has the advantage of being able to store a large quantity of liquid F₃. This is because the height of the storage part 17A can be increased substantially. Thus the sum of the volumes of liquid F₁ moved in the control portions 16(i) substantially equals the volume of liquid F₃ moved. For the same control travel of the interfaces I₁(i) as in the case of a single control portion 16 (FIG. 4A) a larger quantity of liquid F₃ is moved and injected out of the device according to the invention.

In addition, the liquid movement device is particularly compact and can easily be integrated in laboratories on chip.

It also makes it possible to obtain a higher rate for putting a large number of control portions in parallel.

A fifth embodiment of the invention will now be described in detail with reference to FIG. 9. FIG. 9 is a schematic representation in longitudinal section of a part of the microfluidic liquid-movement device, adapted to minimise the influence of the hysteresis of the contact angle.

The hysteresis of the contact angle results in surface defects, such as for example chemical non-homogeneities or surface roughness. The contact angle of a drop placed on a surface is then not unique but comprised between two limit values referred to as the advancing angle and the receding angle. Thus a triple line will advance (or move back) only as from the moment when the contact angle reaches the advancing angle (or respectively the receding angle).

FIG. 9 shows a part of the microchannel 10. The interface I₃, situated in the injection portion, is at rest (dotted line) and forms with the wall a contact angle θ₃ lying between the receding angle θ_{3,R} and the advancing angle θ_{3,A}. When the fluid F₂, under the pressure of the piston liquid F₁, exerts a pressure on the liquid of interest F₃, the interface I₃ will progressively deform without the triple line moving back, as long as the contact angle θ₃ remains different from the receding angle θ_{3,R}. When θ₃ is equal to θ_{3,R}, the triple line moves back in the direction of the second end 12B of the microchannel 10.

This physical behaviour of the interface I₃, due to the hysteresis of the contact angle, has several drawbacks.

Firstly, the existence of the receding angle θ_{3,R}, introduces a kind of pressure barrier to be crossed in order to move the triple line of the interface I₃ and then the liquid F₃. If the pressure force exerted by the liquid F₁ on the liquid F₃ by means of the fluid F₂ is insufficient to pass this pressure barrier, the hysteresis then prevents the movement of the triple line of the liquid F₃ and consequently blocks the movement of the liquid F₁. The movement device is then made inoperative.

Secondly, as explained previously, the triple line of the interface I₃ and next the liquid F₃ are set in motion when the contact angle θ₃ reaches the value of the receding angle θ_{3,R}. Thus, if moreover the fluid F₂ is compressible, a delay time is introduced during which the flow rate of the liquid F₃ through the second opening 11B is not equivalent to the flow rate of the liquid F₁. This may disturb the control of the quantity of liquid F₃ injected out of the device.

For the purpose of minimising the effect of the hysteresis of the contact angle, the height H of the injection portion 17 is made substantially greater than the height h of the control portion 16. This is because the pressure related to the hysteresis phenomena is proportional to H⁻¹. Thus the height H may be between 5 h and 50 h, preferably 10 h.

A connecting portion 18 of the microchannel 10 connects the control portion 16 to the injection portion 17, or more precisely the second end 16B of the control portion 16 is connected to the injection portion 17. The connection portion 18 is filled solely with separating fluid F₂.

The pressure barrier caused by the hysteresis at the triple line of the I₃ interface is then substantially reduced. The risks of blockage of the movement of the liquid F₁ are thus reduced along with the delay time for setting in motion the triple line of the interface I₃.

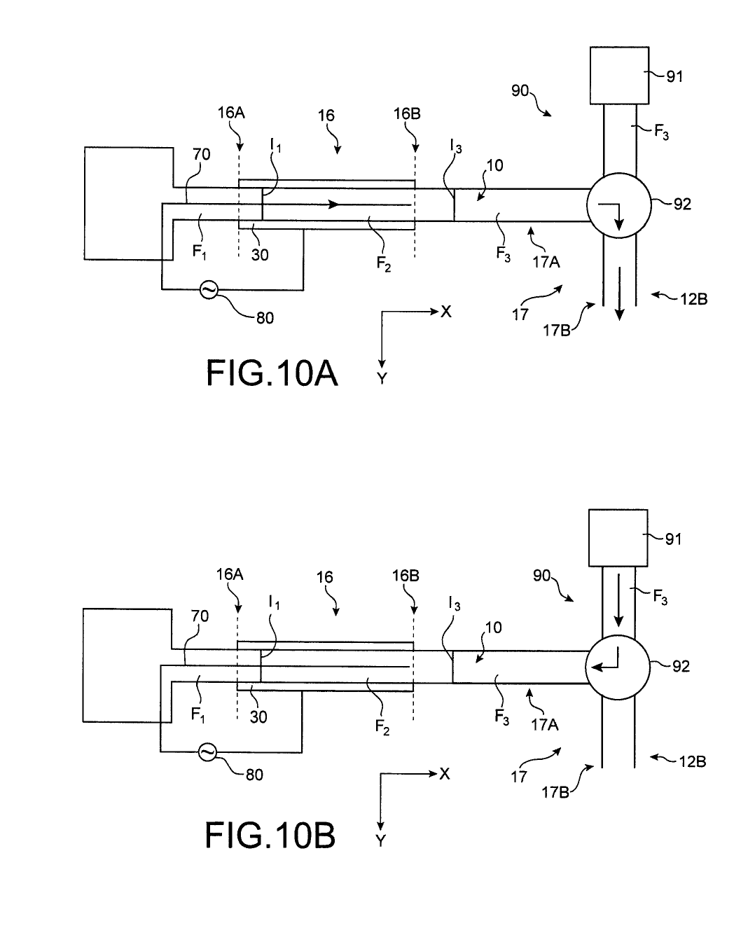

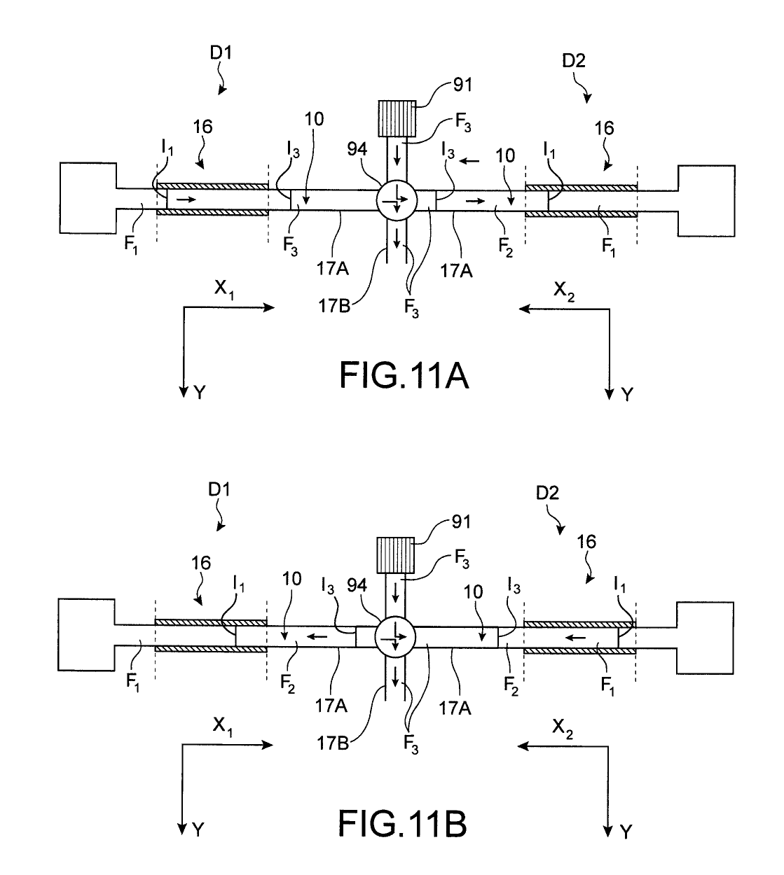

A sixth embodiment of the invention will now be described in detail with reference to FIGS. 10A to 11B.

FIGS. 10A and 10B are schematic representations in longitudinal section of a microfluidic device for the movement of liquid for which the injection portion 17 of the microchannel can be simply filled, after dispensing of the liquid F₃, by the same liquid of interest F₃. The device thus adapted is then able to be used several times.

There is considered here, for illustrative purposes, a liquid-movement device as described in FIG. 4A. However, a device as described in FIGS. 5 to 9 can also be used.

The filling system 90 comprises a reservoir 91 of liquid of interest F₃ connected to the injection portion 17 of the microchannel 10 by means of a L-shaped three-way valve 92. The liquid of interest F₃ stored in the reservoir 91 is injected or sucked by means of a pump or a syringe pusher (not shown).

The L-shaped three-way valve 92 is disposed in the injection portion 17, close to the second end 12B, and thus divides the injection portion into two parts, a first storage part 17A and a second injection part 17B. The first storage part 17A is the part of the injection portion 17 lying between the control portion 16 and the valve 92. It comprises the interface I₃. The second injection part 17B is the part of the injection portion 17 lying between the valve 92 and the second end 12B of the microchannel 10. It is filled with liquid F₃.

The valve can occupy two different states.

A first state is a filling state in which the first storage part 17A communicates with the reservoir 91.

A second state is an injection state in which the first storage part 17A communicates with the second injection part 17B.

Control means (not shown) provide the switching of the L-shaped three-way valve into one of the two defined states.

The switching is carried out according to the position of the interface I₁ in the control portion 16. Thus, when the interface I₁ is substantially close to the first end 16A of the control portion 16, the valve 92 switches into its injection state. When the interface I₁ is substantially close to the second end 16B of the control portion 16, the valve 92 switches into its filling state.

The functioning of the liquid-movement device according to the sixth embodiment is as follows.

As shown by FIG. 10A, the interface I₁ is initially situated close to the first end 16A of the control portion 16. The liquid F₃ substantially fills the first storage part 17A of the injection portion 17 and the valve 92 is in the injection state.

When the electrode 30 is activated, an electrowetting force is applied to the triple line of the interface I₁ and causes the movement of the liquid F₁ in the direction of the second end 16B of the control portion 16. Consequently the liquid F₁ “pushes” the fluid F₂ in the same direction. The liquid of interest F₃ is then set in motion in the direction of the second end 12B of the microchannel 10 and injected out of the device by means of the second opening 11B.

When the interface I₁ arrives at the end of travel (FIG. 10B), that is to say when it arrives substantially close to the second end 16B of the control portion 16, the electrode 30 is deactivated and the valve 92 switches into the filling state.

The reservoir 91 is then put in communication with the storage part 17A of the injection portion 17.

The liquid of interest F₃ stored in the reservoir 91 then progressively fills the storage part 17A of the injection portion 17, under the pressure force exerted on the liquid F₃ in the reservoir 91.

In doing this, it moves the liquid F₁ by means of the fluid F₂ until the interface I₁ is situated substantially at the first end 16A of the control portion 16. The liquid-movement device is then filled.

It should be stated that, because of the absence of an electrical field, there is no electrowetting force applied to the triple line of the interface I₁ that would cause a movement of the liquid F₁ in the direction of the second end 16A of the control portion 16, and would oppose the filling of the microchannel by the liquid F₃. Thus the liquid F₁ can easily be moved by the liquid of interest F₃ from the reservoir 91.

In order to be ready for a further use, the valve 92 switches into its injection state. It then suffices to impose an electrical field between the electrode 30 and the counter-electrode 70 so that, because of the movement of the interface I₁, the liquid of interest F₃ is injected out of the device.

According to a variant shown schematically in FIGS. 11A and 11B, the liquid-movement device is adapted to continuously dispense the liquid of interest F₃.

For this purpose, the liquid-movement device comprises two devices D1 and D2 as described in FIG. 4A and a reservoir 91 containing the liquid of interest F₃.

A reference frame (Xᵢ,Y) is shown in FIG. 11A for each device Di, where i=1,2. Each direction Xᵢ is parallel to the longitudinal direction of the control portion 16 and oriented towards the injection portion 17.

The devices D1 and D2 and the reservoir 91 are connected together by a four-way valve 94 at 90°. The devices D1 and D2 have in common, downstream of the valve 94, the injection part 17B of the injection portion 17.

The two devices D1 and D2 have a structure and functioning similar to what was described with reference to FIGS. 10A and 10B. The different characteristics are simply detailed here.

The valve 94 can switch into two different states.

A first state corresponds to the injection of liquid F₃ from the device D1 and the filling with liquid F₃ of the device D2. For this purpose, the valve 94 puts in communication on the one hand the storage part 17A of the device D1 with the injection part 17B, and on the other hand the reservoir 91 with the storage part 17A of the device D2.

The second state corresponds conversely to the filling with liquid F₃ of the device D1 and to the injection of the device D2 with liquid F₃. For this purpose, the valve 94 puts in communication on the one had the storage part 17A of the device D2 with the injection part 17B, and on the other hand the reservoir 91 with the storage part 17A of the device D1.

The operating principle is as follows.

With reference to FIG. 11A, when the device D2 is filled with the liquid F₃ by the reservoir 91, the device D1 dispenses the liquid F₃ from its storage part 17A, the valve 94 then occupying the first state.

Then, when the interface I₁ of the device D1 arrives substantially at the second end 16B of the control portion 16, the electrical field of the device D1 is deactivated, the valve 94 switches into its second state (FIG. 11B), and the electrical field of the device D2 is activated. The device D2 then dispenses the liquid F₃ from its storage part 17A while the reservoir 91 fills the storage part 17A of the device D1 with liquid F₃.

Thus the liquid of interest F₃ is dispensed out of the device according to the invention continuously rather than in jerks.

Naturally, according to a variant that is not shown, several movement devices can be connected together at the injection part 17B of their respective injection portions 17. Thus, since they dispense liquids of interest F₃ with different compositions and not miscible with each other, it is possible to obtain the continuous dispensing of different slugs of liquids of interest F₃.

In the case where two or more devices according to the variant of the sixth embodiment are connected together at the injection part 17B of their respective injection portions 17, it is possible to obtain the continuous injection of liquids F₃ each occupying part of the transverse section of the injection part 17B of the injection portion 17. The mixing between the respective liquids of interest F₃ can possibly take place by diffusion before injection through the opening 11B of the microchannel 10.

This device makes it possible to inject liquids of interest F₃ that cannot previously be stored together in a reservoir.

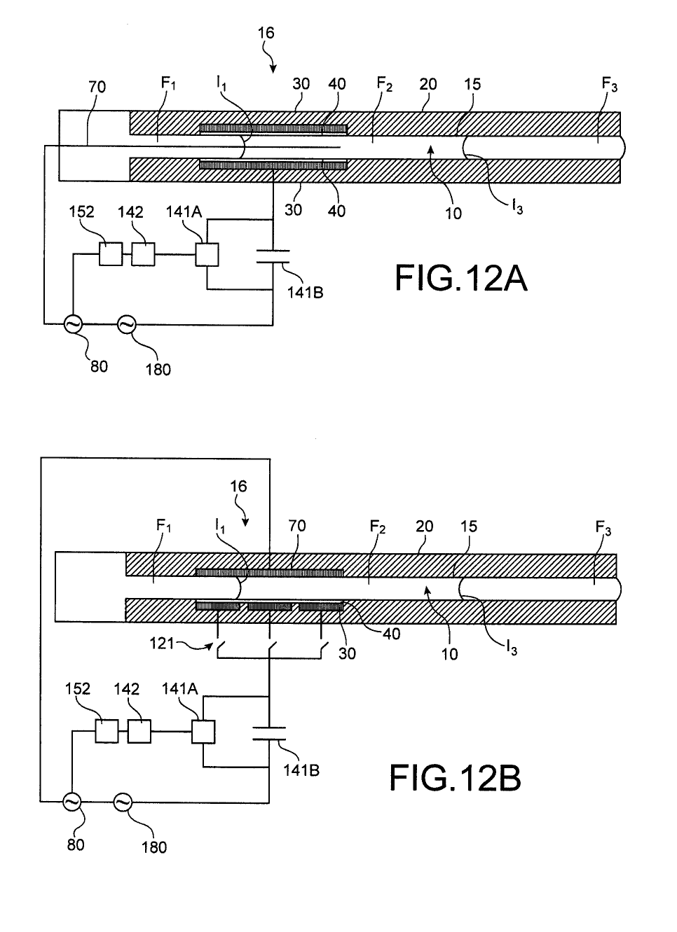

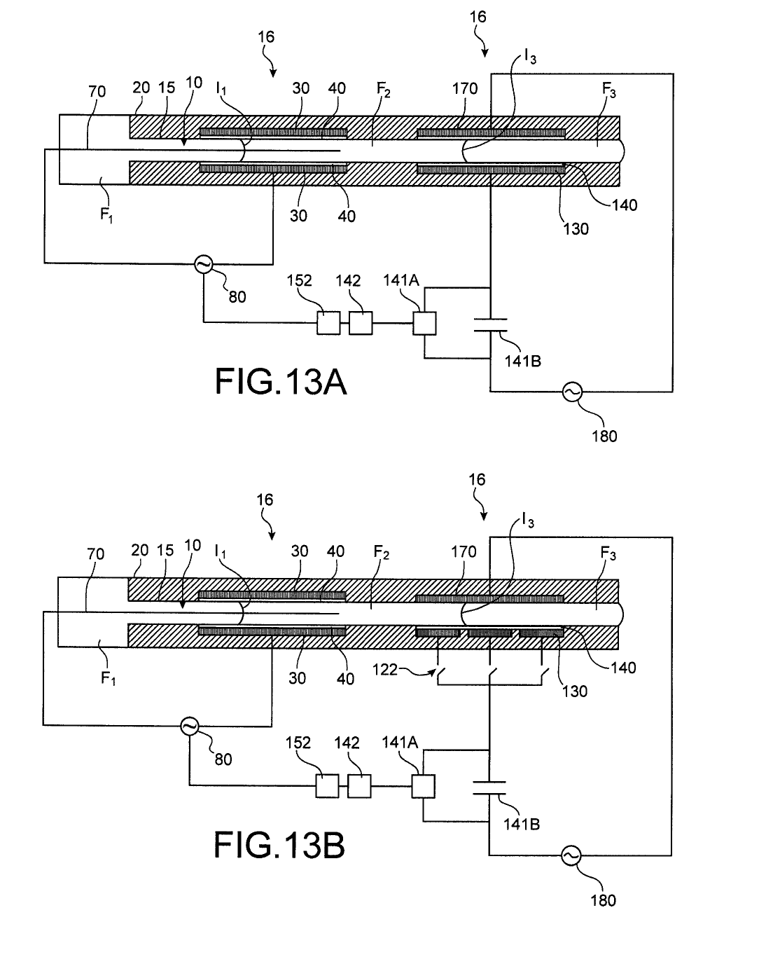

A seventh embodiment of the invention will now be described n detail with reference to FIGS. 12A to 13B, which are schematic representations of the liquid-movement device comprising a system of controlling the movement of the piston liquid F₁, for the purpose of precisely controlling the quantity of liquid of interest F₃ injected.

FIGS. 12A and 12B show the movement device for which the movement of the liquid F₁ depends on the position of the interface I₁.

FIGS. 13A and 13B show variants of the embodiments shown in FIGS. 12A and 12B, for which the movement of the liquid F₁ depends on the position of the interface I₃.

With reference to FIGS. 12A and 12B, the control system comprises a capacitive measuring device for determining the position of the interface I₁ and controlling the movement of the liquid F₁.

In the first embodiment, the device for determining position by capacitive measurement is connected to the electrode 30 and to the counter-electrode 70.

It comprises an AC voltage source 180. The frequency of this is preferably very different from that of the voltage supplied by the voltage source 80. It is advantageously a hundred times higher. For example, it may be around a few hundreds of kilohertz if the frequency of the voltage supplied by the voltage source 80 is around a few kilohertz. The amplitude is preferably around one tenth to one hundredth of that of the voltage delivered by the voltage source 80, and is preferably around a tenth of a volt.

For the purpose of measuring the capacitance formed between the biased liquid F₁ and the electrode 30, a capacitor 141B is put in series with the electrode 30 in order to form a capacitive divider.

The capacitance of the capacitor 141B can be between 10 pF and 500 pF, and is preferably equal to 100 pF.

A voltmeter 141A measures the voltage at the terminals of the capacitor 141B.

In addition, it is possible to replace the capacitor 141B and the voltmeter 141A by an impedance analyser.

The voltage measured is transmitted to means 142 of calculating the position of the interface I₁.

From the measured voltage, the calculation means 142 calculate the capacitance formed between the biased liquid F₁ and the electrode 30 and deduce therefrom the rate of coverage of the dielectric layer 40 by the liquid F₁. From the rate of coverage and knowing the position of the dielectric layer 40, the calculation means 142 determine the position of the interface I₁ in the microchannel 10.

The position of the interface I₁ is next transmitted to control means 152. These are connected to the voltage source 80 and make it possible to vary the voltage generated.

The variation in the voltage generated by the voltage source 80 makes it possible to control in particular the speed of movement of the liquid F₁.

The calculation means 142 and the control means 152 are for example disposed on a printed circuit (not shown).

Thus the control system controls the movement of the liquid F₁ according to the position of the interface I₁ detected by capacitive measurement.

The functioning of the device for the controlled movement of liquid according to the first embodiment of the invention is as follows.

The voltage source 80 activates the electrode 30 and allows movement of the liquid F₁.

Activation of the voltage source 180 makes it possible to measure the capacitance formed between the biased liquid F₁ and the electrode 30. For this purpose, the voltmeter 141A of the capacitive measuring device measures the voltage at the terminals of the capacitor 141B and sends the measured signal to the calculation means 142.

The means 142 of calculating the position of the interface I₁ make it possible to obtain from the measured voltage the rate of coverage of the dielectric layer 40 by the liquid F₁ and deduce therefrom the position of the interface I₁. The position of the interface I₁ is transmitted to the control means 152.

According to the signal received, the control means 152 determine the potential difference to be applied by the voltage source 80.

According to the intensity of the potential difference applied by the voltage source 80, a greater or lesser electrowetting force is generated at the interface I₁. Its intensity makes it possible to control in particular the speed of movement of the liquid F₁.

The electrowetting force thus causes the movement of the liquid F₁ in the direction X, which “pushes” the fluid F₂, and thus the liquid F₃, in the same direction.

FIG. 12B shows a variant of the embodiment shown in FIG. 12A.

A matrix of electrodes 30 is disposed on one face of the microchannel 10.

The counter-electrode 70 is here an electrode formed on part of the internal wall 15 of the microchannel 10 opposite the matrix of electrodes 30. It can however be a catenary wire (FIG. 2) or a buried wire.

Switching means 121 are provided for activating an electrode 30(i) of the matrix of electrodes 30. Closure thereof establishes contact between the electrode 30(i) and the voltage source 80. The switching means 121 are controlled by an activation pilot (not shown).

When the electrode 30(1) situated close to the interface I₁ is activated, by the switching means 121, the dielectric layer 40 between this activated electrode and the liquid under tension acts as a capacitor.

The liquid F₁ can be moved gradually, over the hydrophobic surface, by successive activation of the electrodes 30(1), 30(2) . . . etc.

Advantageously, the substrate 20, in the case where it is slightly conductive, for example made from silicon, is taken to a given potential. For example, it may be grounded.

For this purpose, an electrode (not shown) in the form of a metal layer can advantageously be formed on the external wall of the substrate 20 opposite the matrix of electrodes 30. It can extend over the entire length of the matrix of electrodes 30.

Taking the substrate 20 to a given potential avoids electrostatic disturbance between the electrodes 30 of the matrix that may interfere with the capacitance measuring signal. Measurement of the capacitance is then more precise, which improves the general precision of functioning of the control system.

FIGS. 13A and 13B are schematic representations in longitudinal section of a liquid-movement device according to a variant of the seventh embodiment of the invention, for which the detected interface is different from that subjected to the electrowetting forces.

According to this embodiment of the invention, the control system is adapted to control the movement of the liquid F₁ according to the position of an interface I₃. The liquid F₃ is here electrically conductive but it may also be dielectric, as explained below.

In the same way as in the first embodiment, the movement of the liquid F₁ is provided by activation of the electrode 30 connected to a voltage source 80.

The capacitive measuring device of the control system comprises at least one electrode 130 formed on the internal wall 15 of the microchannel 10 and extends in the longitudinal direction of the microchannel 10. It is said to be buried and extends over part or all of the perimeter of the microchannel 10.

The length of the electrode 130 defines a detection portion 160. The interface I₃ is situated in the detection portion 160.

A counter-electrode 170 is formed on the internal wall 15 of the microchannel 10 opposite the electrode 130. The counter-electrode 170 may also be a buried wire, or be disposed in the microchannel 10 in the form of a catenary wire, for example a wire made from Au.

The counter-electrode 170 preferably extends in the microchannel 10 opposite the electrode 130.

The voltage source 180 is connected to the electrodes 130 and 170 in order to apply an alternating voltage according to the same characteristics described above. The mean value of the voltage is zero and the frequency high in order to avoid causing the deformation of the curvature of the interface F₃, which would interfere with the capacitive measurement.

With reference to FIG. 13A, the capacitive measuring device also comprises a dielectric layer 140 that directly covers the electrode 130.

When the voltage source 180 is activated, the dielectric layer 140 between the electrode 130 and the liquid under tension F₃ acts as a capacitor.

The capacitance of this capacitor can be deduced from the voltage measured at the terminals of a reference capacitor 141B connected in series to the electrode 130.

The calculation means 142 make it possible to calculate the position of the interface I₃, from the voltage measurement by the voltmeter 141A at the terminals of the capacitor 141B.

The control means 152 control the level of the voltage generated by the voltage source 80 according to the position of the interface I₃.

Thus the control system controls the movement of the liquid F₁ according to the position of the interface I₃ determined by capacitive measurement.

With reference to FIG. 13B, the electrode 130 can be replaced by a matrix of electrodes 130. Switching means 122 can be provided for activating the electrode 130(i) at which the interface I₃ is situated. Closure thereof establishes contact between the corresponding electrode 130(i) and the voltage source 180. The switching means 122 are controlled by an activation pilot (not shown).

Advantageously, as described previously, the substrate 20, in the case where it is slightly conductive, for example made from silicon, is taken to a given potential. For example, it may be grounded.

For this purpose, an electrode (not shown) in the form of a metal layer can advantageously be formed on the external wall of the substrate 20 opposite the matrix of electrodes 130. It may extend over the entire length of the matrix of electrodes 130.

In the case where the liquid F₃ is dielectric and has a permittivity different from that of the fluid F₂, the dielectric layer 140 is no longer necessary.

This is because, when the voltage source 180 is activated, measurement of the voltage at the terminals of the capacitor 141B makes it possible to deduce the capacitance formed by the fluids F₂ and F₃ between the electrodes 130 and 170. This capacitance depends on the position of the interface I₃.

The control system comprises the same components as described previously and has identical functioning.

In a supplementary embodiment of the invention, not shown, the control system can also be adapted to detect both the position of the interface I₁ and that of the interface I₃, for the purpose of obtaining greater precision on the quantity of liquid F₃ moved. This situation is particularly suitable in the case where the fluid F₂ has compressibility that it is necessary to assess in the real time, or when the liquids F₁ and F₃ have uncontrolled evaporation.

This detection also makes it possible to measure the injection rate, which makes it possible to verify that the channel is not blocked, or even to detect the presence of a leak.

Moreover, it should be noted that, in all the embodiments described above, the surface of the channels, and particularly at the control portion, may be smooth, rough or have a micro or nano structure so as to amplify the wetting effects and increase the capillarity forces, and therefore the pumping pressure.

1. Liquid-movement device, comprising at least one substrate (20; 21, 22, 23) comprising a microchannel (10), said microchannel (10) comprising a first end (12A) and a second end (12B), substantially opposite to each other in the longitudinal direction of the microchannel (10), an opening onto the surrounding environment being situated substantially at said second end (12B),
said device comprises:
a first liquid (F₁) partially filling the microchannel (10) in the longitudinal direction of the microchannel (10),
a fluid (F₂) situated downstream of said first liquid (F₁) in the direction of the second end (12B) and forming with the first liquid (F₁) a first interface, said first interface (I₁) being situated in a control portion (16) of the microchannel (10), and
a second liquid (F₃) situated downstream of said fluid (F₂) in the direction of the second end (12B) and forming with the fluid (F₂) a second interface (I₃),
characterised in that
the device comprises means of moving the first liquid (F₁) by electrowetting, the first liquid (F₁) being electrically conductive and the fluid (F₂) electrically insulating, the movement of the first liquid (F₁) causing the movement of the second liquid (F₃), via the fluid (F₂), through said opening (11B).

2. Liquid-movement device according to claim 1, characterised in that said means of moving the first liquid (F₁) by electrowetting comprise:
at least one first electrically conductive means (30; 20, 21),
a layer of a dielectric material (40) directly covering the first conductive means (30; 20, 21), said dielectric layer (40) being at least partially wetted by said first liquid (F₁),
at least one second electrically conductive means (70) forming a counter-electrode, in contact with the first liquid (F₁), and
a first voltage generator (80) for applying a potential difference between said first and second conductive means.

3. Liquid-movement device according to claim 2, characterised in that, the substrate (20, 21) comprising the control portion (16) being electrically conductive, the first electrically conductive means (30) comprises the conductive substrate (20, 21).

4. Liquid-movement device according to claim 2, characterised in that,
the microchannel (10) comprising an injection portion (17) extending substantially from the opening (11) in the direction of the control portion (16), said second interface (I₃) being situated in the injection portion (17),
a stack (34) of a first layer of a dielectric material (40), an electrically conductive means being able to be taken to a given potential (V0′), and a second layer of a dielectric material (40), each having a length substantially equal in the longitudinal direction of the injection portion (17), is disposed on the internal wall (15) of the injection portion (17) so as to electrically insulate the second liquid (F₃) from the conductive substrate (20, 21).

5. Liquid-movement device according to claim 2, characterised in that said first electrically conductive means (30) comprises at least one electrode (30) disposed on at least part of the wall in the longitudinal direction of the microchannel (10) and situated in the control portion (16).

6. Liquid-movement device according to claim 5, characterised in that said first electrically conductive means (30) comprises an electrode (30) extending over the entire length of the control portion (16).

7. Liquid-movement device according to claim 1, characterised in that it comprises a reservoir (60) communicating with the microchannel (10) through an opening (11A) situated at the first end (12A) and containing said first conductive liquid (F₁).

8. Liquid-movement device according to claim 5, characterised in that said first electrically conductive means (30) comprises a matrix of electrodes (30) extending over the entire length of the control portion (16).

9. Liquid-movement device according to claim 8, characterised in that the first liquid (F₁) forms a liquid slug surrounded by fluid (F₂) so as to form a rear interface (I_{1,R}) and a front interface (I_{1,A}), the two interfaces (I_{1,R}, I_{1,A}) being situated in the control portion (16).

10. Liquid-movement device according to claim 9, characterised in that the movement of the first interface (I₁) in the direction of the first end (12A) of the microchannel (10) causes an aspiration of the second liquid (F₃) through the opening (11B) in the direction of the first end (12A).

11. Liquid-movement device according to claim 5, characterised in that said electrode (30) comprises two parts parallel to each other.

12. Liquid-movement device according to claim 5, characterised in that said electrode (30) extends over the entire perimeter of the control portion (16).

13. Liquid-movement device according to claim 2, characterised in that said layer of dielectric material (40) is covered directly by a layer of hydrophobic material (50).

14. Liquid-movement device according to claim 1, characterised in that the microchannel has a convex polygonal transverse section.

15. Liquid-movement device according to claim 1, characterised in that the microchannel has a substantially circular transverse section.

16. Liquid-movement device according to claim 1, characterised in that the microchannel has a plurality of control portions disposed in series, each control portion (16(i)) being partially filled with the first liquid (F₁(i)) and fluid (F₂(i)).

17. Liquid-movement device according to claim 1, characterised in that the microchannel has a plurality of control portions disposed in parallel, each control portion (16(i)) being partially filled with the first liquid (F₁(i)) and fluid (F₂(i)).

18. Liquid-movement device according to claim 1, characterised in that,
the microchannel (10) comprising an injection portion (17) extending substantially from the opening (11B) in the direction of the control portion (16), said second interface (I₃) being situated in the injection portion (17),
the longitudinal axis of the control portions (16) is substantially perpendicular to the longitudinal axis of the injection portion (17).

19. Liquid-movement device according to claim 1, characterised in that,
the microchannel (10) comprising an injection portion (17) extending substantially from the opening (11B) in the direction of the control portion (16), said second interface (I₃) being situated in the injection portion (17),
the height (H) of the injection portion (17) is substantially greater than the height (h) of the control portion (16).

20. Liquid-movement device according to claim 19, characterised in that the height (H) of the injection portion (17) is between approximately 10 and 50 times the height (h) of the control portion (16).

21. Liquid-movement device according to claim 19, characterised in that a connecting portion (18) connects the control portion (16) to the injection portion (17), the connecting portion (18) being filled only with fluid (F₂).
